(19) United States
(12) Patent Application Publication
(10) Pub. No.: US 2026/0371847 A1
(43) Pub. Date: Nov. 19, 2026

(54) DISPLAY PANEL AND ELECTRONIC DEVICE

(71) Applicant: Samsung Display Co., Ltd., Yongin-si (KR)

(72) Inventors: Kangmoon JO, Yongin-si (KR); Bogyeong KIM, Yongin-si (KR); Donghyeon KI, Yongin-si (KR); Seungsoo BAEK, Yongin-si (KR); Seongyoung LEE, Yongin-si (KR)

(73) Assignee: Samsung Display Co., Ltd., Yongin-si (KR)

(21) Appl. No.: 19/674,540

(22) Filed: May 12, 2026

(30) Foreign Application Priority Data
May 14, 2025 (KR) 10-2025-0062820

(51) Int. Cl. H10K 59/121; H10K 59/131

(52) U.S. Cl. CPC H10K 59/1213; H10K 59/1216; H10K 59/131

(57) ABSTRACT

A display panel may include a substrate, a first transistor including a first semiconductor layer, a second transistor including a second semiconductor layer, a first conductive layer including a first gate electrode of the first transistor that overlaps a channel area of the first semiconductor layer in a plan view, a first bridge connecting the first conductive layer to the second semiconductor layer, a lower conductive layer between the substrate and the first conductive layer, the lower conductive layer overlapping, in the plan view, a contact point between the first conductive layer and the first bridge, and a light-emitting diode including a pixel electrode connected to the first transistor.

### CROSS-REFERENCE TO RELATED APPLICATION

This application is based on and claims priority under 35 U.S.C. §119 to Korean Patent Application No. 10-2025-0062820, filed on May 14, 2025, in the Korean Intellectual Property Office, the disclosure of which is incorporated by reference herein in its entirety.

### BACKGROUND

### Field

One or more embodiments provide a display panel and an electronic device including the same.

### Description of Related Art

Display panels have recently been used in electronic devices for various purposes. As the applications of display panels have become more diverse, the demand for high-quality display panels has increased.

### SUMMARY

One or more embodiments provide a display panel for implementing high-quality images and an electronic device including the same.

According to one or more embodiments, a display panel may include a substrate, a first transistor including a first semiconductor layer, a second transistor including a second semiconductor layer, a first conductive layer including a first gate electrode of the first transistor that overlaps a channel area of the first semiconductor layer in a plan view, a first bridge connecting the first conductive layer to the second semiconductor layer, a lower conductive layer between the substrate and the first conductive layer, the lower conductive layer overlapping, in the plan view, a contact point between the first conductive layer and the first bridge, and a light-emitting diode including a pixel electrode connected to the first transistor.

According to one or more embodiments, an electronic device may include: a substrate; a plurality of pixel circuits on the substrate; and a first light-emitting diode connected to a first pixel circuit among the plurality of pixel circuits, wherein the first pixel circuit may include: a driving transistor including a first semiconductor layer; a data write transistor including a second semiconductor layer; a first conductive layer including a first gate electrode of the driving transistor that overlaps a channel area of the first semiconductor layer in a plan view; a first bridge connecting the first conductive layer to the second semiconductor layer; and a lower conductive layer between the substrate and the first conductive layer, the lower conductive layer overlapping, in the plan view, a contact point between the first conductive layer and the first bridge.

According to one or more embodiments, a display panel may include: a pixel circuit; and a light-emitting diode connected to the pixel circuit. The pixel circuit may include: a driving transistor configured to supply a driving power voltage to the light-emitting diode, the driving transistor including a first semiconductor layer; a data write transistor configured to be turned on by a scan signal to connect a data line to a gate electrode of the driving transistor, the data write transistor including a second semiconductor layer; a first conductive layer including the gate electrode of the driving transistor; a bridge connecting the first conductive layer to the second semiconductor layer; an upper conductive layer above the first conductive layer; and a lower conductive layer below the first conductive layer, and overlapping, in a plan view, a contact point between the first conductive layer and the bridge.

### BRIEF DESCRIPTION OF DRAWINGS

The above and other aspects, features, and advantages of certain embodiments of the disclosure will be more apparent from the following description taken in conjunction with the accompanying drawings, in which:

FIG. 1A is a block diagram of an electronic device according to an embodiment;

FIG. 1B schematically illustrates electronic devices according to various embodiments;

FIG. 2 is a schematic plan view of a display panel according to an embodiment;

FIG. 3 is a schematic cross-sectional view of a display panel according to an embodiment;

FIG. 4 illustrates optical units of a color conversion-transmitting layer of a display panel, according to an embodiment;

FIG. 5 is an equivalent circuit diagram of a light-emitting diode included in a display panel and a pixel circuit electrically connected to the light-emitting diode, according to an embodiment;

FIG. 6 is a plan view illustrating a first pixel circuit to a third pixel circuit and a first light-emitting diode to a third light-emitting diode arranged in a display area of a display panel, according to an embodiment;

FIG. 7 is a cross-sectional view of a display panel according to an embodiment, taken along a line VII-VII’ of FIG. 6;

FIGS. 8 to 12 are cross-sectional views illustrating a manufacturing process of a display panel, according to an embodiment;

FIG. 13 is an enlarged view of a portion of a display panel according to an embodiment and corresponds to a plan view of enlarged region XIII of FIG. 12; and

FIG. 14 is a plan view of an enlarged portion of a display panel, according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b, or c” indicates only a, only b, only c, both a and b, both a and c, both b and c, all of a, b, and c, or variations thereof.

As the disclosure allows for various changes and numerous embodiments, particular embodiments will be shown in the drawings and described in detail in the written description. The attached drawings for illustrating embodiments of the disclosure are referred to in order to gain a sufficient understanding of the present disclosure, the merits thereof, and the objectives accomplished by the implementation of the disclosure. The disclosure may, however, be embodied in many different forms and should not be construed as being limited to the embodiments set forth herein.

Hereinafter, one or more embodiments of the disclosure will be described in detail with reference to the accompanying drawings. Like elements in the drawings denote like elements, and repeated descriptions thereof are omitted.

It will be understood that although the terms “first,” “second,” etc. may be used herein to describe various elements, these elements should not be limited by these terms, and these elements are only used to distinguish one element from another.

As used herein, the singular forms “a,” “an,” and “the” are intended to include the plural forms as well, unless the context clearly indicates otherwise.

It will be further understood that the terms “comprises” and/or “comprising” used herein specify the presence of stated features or elements, but do not preclude the presence or addition of one or more other features or elements.

It will be understood that when a layer, region, or element is referred to as being “formed on” another layer, region, or element, it can be directly or indirectly formed on the other layer, region, or element. That is, for example, intervening layers, regions, or elements may be present.

Sizes of elements in the drawings may be exaggerated for convenience of explanation. In other words, since sizes and thicknesses of elements in the drawings are arbitrarily illustrated for convenience of explanation, the following embodiments are not limited thereto.

When a certain embodiment may be implemented differently, a specific process order may be performed differently from the described order. For example, two consecutively described processes may be performed substantially at the same time or performed in an order opposite to the described order.

It will be understood that when a layer, region, or component is referred to as being connected to another layer, region, or component, it can be directly or indirectly connected to the other layer, region, or component. For example, when a layer, region, or component is referred to as being electrically connected to another layer, region, or component, it can be directly or indirectly electrically connected to the other layer, region, or component.

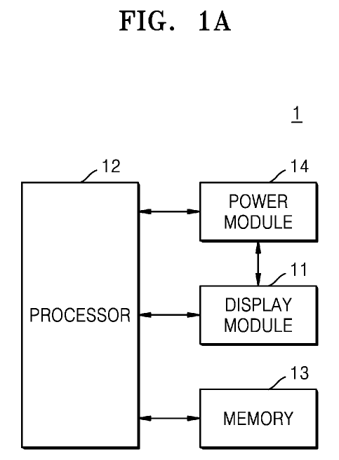

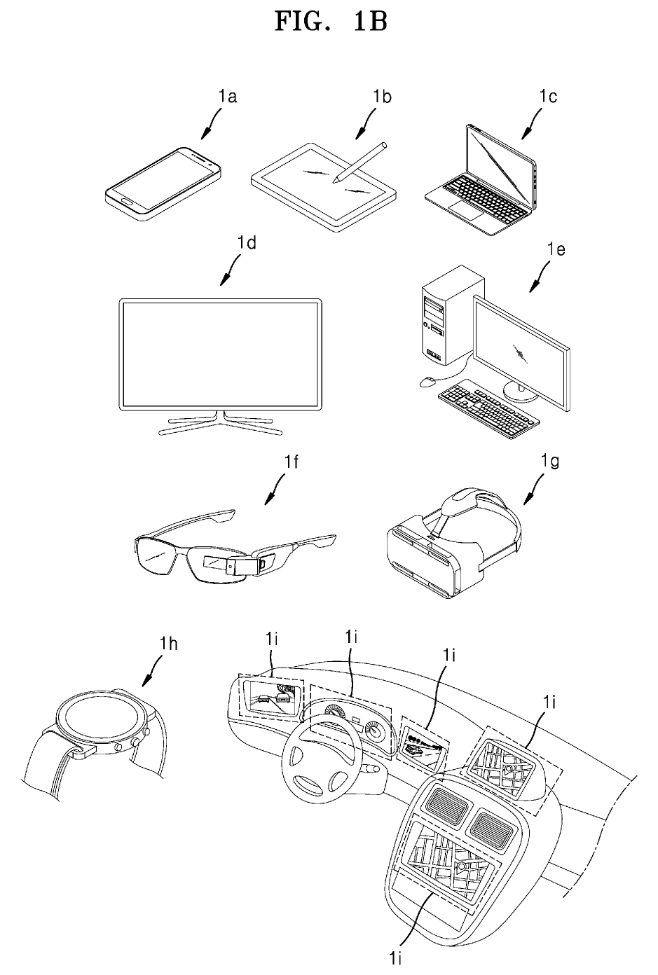

FIG. 1A is a block diagram of an electronic device according to an embodiment. FIG. 1B schematically illustrates electronic devices according to various embodiments.

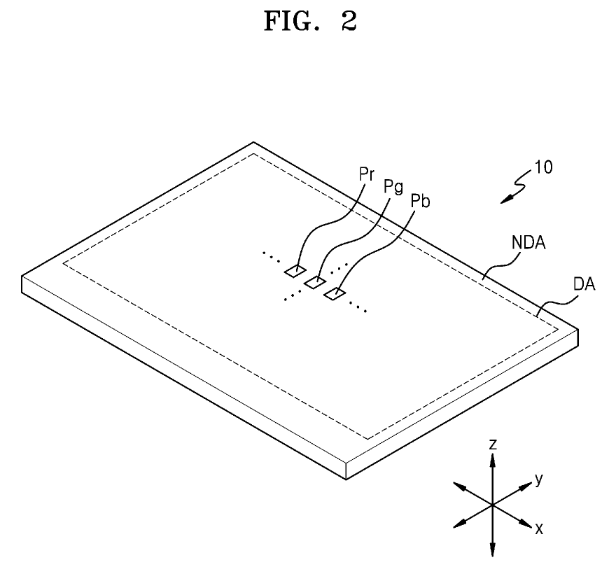

Referring to FIG. 1A, an electronic device 1 according to an embodiment may include a display module 11, a processor 12, a memory 13, and a power module 14. The display module 11 may include a display panel 10 (see FIG. 2) according to embodiments. In some embodiments, the display module 11 may include the display panel 10 (see FIG. 2), a gate driver, and a data driver. In an embodiment, the display panel 10 (see FIG. 2), the gate driver, and/or the data driver may be simultaneously formed in the process of forming the display panel 10 (see FIG. 2), and in this case, the display panel 10 (see FIG. 2) may correspond to the display module 11. In an embodiment, the gate driver and/or the data driver may be arranged on the display panel 10 (see FIG. 2) and may be electrically connected to the same through a bonding structure.

The processor 12 may include at least one of a Central Processing Unit (CPU), an Application Processor (AP), a Graphics Processing Unit (GPU), a Communication Processor (CP), an Image Signal Processor (ISP), and a controller.

In the memory 13, data information required for the operation of the processor 12 or the display module 11 may be stored. When the processor 12 executes an application stored in the memory 13, an image data signal and/or an input control signal may be transmitted to the display module 11, and the display module 11 may process such signals to output image information through a display screen.

The power module 14 may include a power supply module, such as a power adaptor or a battery device, and a power conversion module that generates power required for the operation of the electronic device 1 by converting the power supplied by the power supply module.

At least one of the components of the electronic device 1 described above may be included in a display device including the display module 11. In addition, some of individual modules functionally included in a single module may be included in the display device, and others thereof may be provided separately from the display device. For example, the display device may include the display module 11, and the processor 12, the memory 13, and the power module 14 may be provided as different devices within the electronic device 1, rather than being part of the display device.

Referring to FIG. 1B, the electronic device according to embodiments may include: electronic devices for image display, such as a smartphone 1a, a tablet personal computer (PC) 1b, a laptop 1c, a television (TV) 1d, and a desktop monitor 1e; wearable electronic devices including display modules, such as smart glasses 1f, a head-mounted display 1g, and a smart watch 1h; and vehicle electronic devices 1i including display modules, such as a vehicle instrument cluster, a center fascia, a Center Information Display (CID) mounted on a dashboard, and a room-mirror display.

FIG. 2 is a schematic plan view of the display panel 10 according to an embodiment.

Referring to FIG. 2, the display panel 10 may include a display area DA and a non-display area NDA outside the display area DA. The display panel 10 may provide an image through an array of pixels that are two-dimensionally arranged on an x-y plane in the display area DA. The pixels include a first pixel, a second pixel, and a third pixel. Hereinafter, for convenience of explanation, the first pixel may be a green pixel Pg, the second pixel may be a red pixel Pr, and the third pixel may be a blue pixel Pb; however, one or more embodiments are not limited thereto.

The red pixel Pr, the green pixel Pg, and the blue pixel Pb may be areas where red light, green light, and blue light may be emitted, respectively, and the display panel 10 may provide an image by using light emitted from the pixels.

The non-display area NDA may be an area where no images are displayed and may entirely surround the display area DA. In the non-display area NDA, drivers or main voltage lines (e.g., a common main voltage line, a driving main voltage line, etc.) configured to provide electrical signals or power to pixel circuits may be arranged. In the non-display area NDA, a pad that may be electrically connected to an electronic component or a printed circuit board may be included.

The display area DA may have a polygonal shape including a rectangular shape, as illustrated in FIG. 2. For example, the display area DA may have a rectangular shape in which the horizontal length is greater than the vertical length, a rectangular shape in which the horizontal length is less than the vertical length, or a square shape. Alternatively, the display area DA may have various shapes, such as an oval shape or a circular shape.

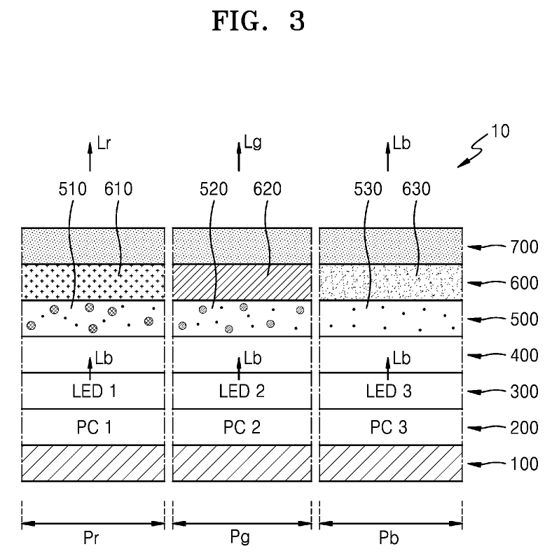

FIG. 3 is a schematic cross-sectional view of each pixel of the display panel 10, according to an embodiment.

Referring to FIG. 3, the display panel 10 may include a circuit layer 200 on a substrate 100. The circuit layer 200 may include a first pixel circuit PC1, a second pixel circuit PC2, and a third pixel circuit PC3, and the first pixel circuit PC1 to the third pixel circuit PC3 may be electrically connected to a first light-emitting diode LED1, a second light-emitting diode LED2, and a third light-emitting diode LED3 of a light-emitting diode layer 300, respectively.

The first light-emitting diode LED1 to the third light-emitting diode LED3 may include organic light-emitting diodes including organic materials. In another embodiment, the first light-emitting diode LED1 to the third light-emitting diode LED3 may be inorganic light-emitting diodes including inorganic materials. The inorganic light-emitting diode may include a PN junction diode including materials based on an inorganic semiconductor. When a voltage is applied to the PN junction diode in a forward direction, electrons and holes may be injected, and the energy generated from the recombination of the electrons and holes may be converted into light energy so that light of a certain color may be emitted. The inorganic light-emitting diode described above may have a width ranging from several to several hundred micrometers or from several to several hundred nanometers. In some embodiments, the light-emitting diode LED may be a light-emitting diode including quantum dots. As described above, an emission layer of the light-emitting diode LED may include organic materials, inorganic materials, quantum dots, both organic materials and quantum dots, or both inorganic materials and quantum dots.

The first light-emitting diode LED1 to the third light-emitting diode LED3 may emit light having the same color. For example, light (e.g., blue light Lb) emitted from the first light-emitting diode LED1 to the third light-emitting diode LED3 may pass through an encapsulation layer 400 on the light-emitting diode layer 300 and then through a color conversion-transmitting layer 500.

The color conversion-transmitting layer 500 may include optical units that convert the color of the light (e.g., the blue light Lb) emitted from the light-emitting diode layer 300, and an optical unit that transmit the emitted light without converting the color of the emitted light. For example, the color conversion-transmitting layer 500 may include color converters configured to convert the light (e.g., the blue light Lb) from the light-emitting diode layer 300 into light of another color, and a penetration unit configured to transmit the light (e.g., the blue light Lb) emitted from the light-emitting diode layer 300 without color conversion. The color conversion-transmitting layer 500 may include a first color converter 510 corresponding to the red pixel Pr, a second color converter 520 corresponding to the green pixel Pg, and a penetration unit 530 corresponding to the blue pixel Pb. The first color converter 510 may convert the blue light Lb into red light Lr, and the second color converter 520 may convert the blue light Lb into green light Lg. The penetration unit 530 may allow the blue light Lb to pass through without color conversion.

A color layer 600 may be on the color conversion-transmitting layer 500. The color layer 600 may include a first color filter 610 to a third color filter 630 having different colors. For example, the first color filter 610 may be a red color filter, the second color filter 620 may be a green color filter, and the third color filter 630 may be a blue color filter.

The light that is color-converted and transmitted through the color conversion-transmitting layer 500 may pass through the first color filter 610 to the third color filter 630, thereby improving color purity. Also, the color layer 600 may prevent or reduce external light (e.g., light that is incident towards the display panel 10 from the outside thereof) from being reflected and viewed by users.

A light-transmissive substrate layer 700 may be on the color layer 600. The light-transmissive substrate layer 700 may include glass or a light-transmissive organic material. For example, the light-transmissive substrate layer 700 may include a light-transmissive organic material such as acryl-based resin.

In an embodiment, the light-transmissive substrate layer 700 is a type of substrate, and after the color layer 600 and the color conversion-transmitting layer 500 are formed on the light-transmissive substrate layer 700, the color conversion-transmitting layer 500 may be integrated with the encapsulation layer 400 to face the encapsulation layer 400.

In another embodiment, after the color conversion-transmitting layer 500 and the color layer 600 are sequentially formed on the encapsulation layer 400, the light-transmissive substrate layer 700 may be formed on the color layer 600 through the direct spreading and hardening of the light-transmissive substrate layer 700. In some embodiments, other optical films such as an anti-reflection (AR) film may be arranged on the light-transmissive substrate layer 700.

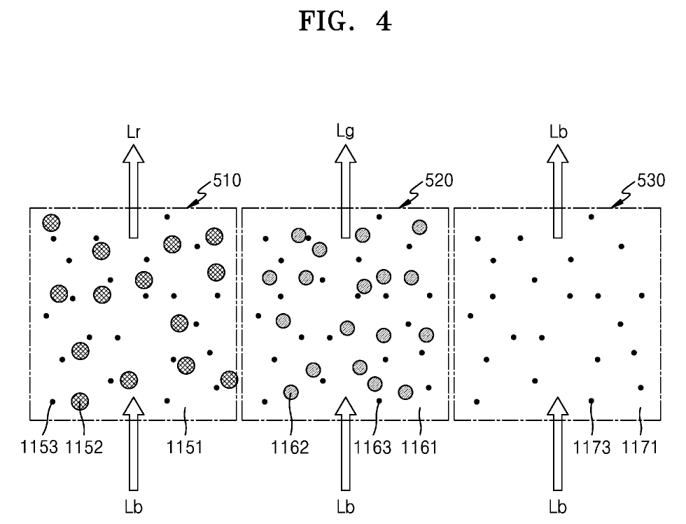

FIG. 4 illustrates optical units of the color conversion-transmitting layer 500 of the display panel 10, according to an embodiment.

Referring to FIG. 4, the first color converter 510 may convert the incident blue light Lb into the red light Lr. As shown in FIG. 4, the first color converter 510 may include a first photosensitive polymer 1151, first quantum dots 1152, and first scattering particles 1153 that are spread on the first photosensitive polymer 1151.

The first quantum dots 1152 may be excited by the blue light Lb and isotropically emit the red light Lr having a greater wavelength than the blue light Lb. The first photosensitive polymer 1151 may include an organic material that is light-transmissive. The first scattering particles 1153 may increase the color conversion efficiency by scattering the blue light Lb, which has not yet been absorbed by the first quantum dots 1152, so that more first quantum dots 1152 may be excited. The first scattering particles 1153 may be, for example, titanium oxide (TiO₂) or metal particles. The first quantum dots 1152 may be selected from among II-VI group compounds, III-V group compounds, IV-VI group compounds, IV group elements, IV group compounds, and a combination thereof.

The second color converter 520 may convert the incident blue light Lb into the green light Lg. As shown in FIG. 4, the second color converter 520 may include a second photosensitive polymer 1161, second quantum dots 1162 and second scattering particles 1163 that are spread on the second photosensitive polymer 1161.

The second quantum dots 1162 may be excited by the blue light Lb and isotropically emit the green light Lg having a greater wavelength than the blue light Lb. The second photosensitive polymer 1161 may include an organic material that is light-transmissive.

The second scattering particles 1163 may increase the color conversion efficiency by scattering the blue light Lb, which has not yet been absorbed by the second quantum dots 1162, so that more second quantum dots 1162 may be excited. The second scattering particles 1163 may be, for example, TiO₂ or metal particles. The second quantum dots 1162 may be selected from among II-VI group compounds, III-V group compounds, IV-VI group compounds, IV group elements, IV group compounds, and a combination thereof.

In some embodiments, the first quantum dots 1152 may include the same materials as the second quantum dots 1162. In this case, the sizes of the first quantum dots 1152 may be greater than those of the second quantum dots 1162.

The penetration unit 530 may allow the blue light Lb, which is incident to the penetration unit 530, to pass through without converting the same. As shown in FIG. 4, the penetration unit 530 may include a third photosensitive polymer 1171 on which third scattering particles 1173 are spread. The third photosensitive polymer 1171 may include an organic material, for example, silicon resin or epoxy resin, which is light-transmissive and may include the same material as the first photosensitive polymer 1151 and the second photosensitive polymer 1161. The third scattering particles 1173 may scatter and emit the blue light Lb and include the same material as the first scattering particles 1153 and the second scattering particles 1163.

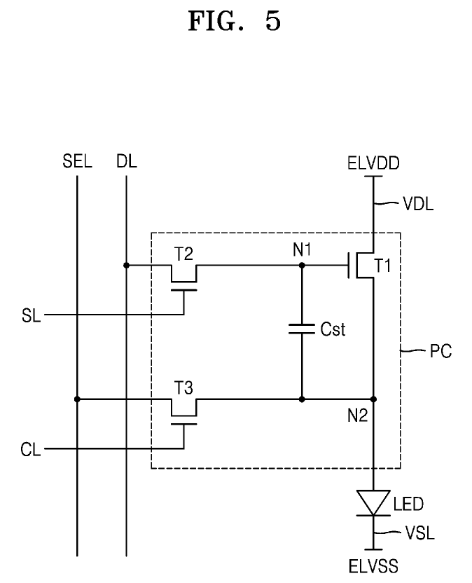

FIG. 5 is an equivalent circuit diagram of a light-emitting diode included in the display panel 10 (see FIG. 2) and a pixel circuit electrically connected to the light-emitting diode, according to an embodiment.

Referring to FIG. 5, a pixel electrode (e.g., an anode) of a light-emitting diode LED, e.g., the light-emitting diode LED, may be connected to a pixel circuit PC, and an opposite electrode (e.g., a cathode) of the light-emitting diode LED may be connected to a common voltage line VSL configured to provide a common power voltage ELVSS. The light-emitting diode LED may emit light at a brightness corresponding to the amount of current provided from the pixel circuit PC.

The light-emitting diode LED of FIG. 5 may correspond to each of the first light-emitting diode LED1 to the third light-emitting diode LED3 shown in FIG. 3, and the pixel circuit PC of FIG. 5 may correspond to each of the first pixel circuit PC1 to the third pixel circuit PC3 shown in FIG. 3.

The pixel circuit PC may control the amount of current flowing from the driving voltage line VDL, which is configured to provide the driving power voltage ELVDD, to the common voltage line VSL, which is configured to provide the common power voltage ELVSS, through the light-emitting diode LED, in response to the data signal. The pixel circuit PC may include a first transistor T1, a second transistor T2, a third transistor T3, and a storage capacitor Cst.

The first transistor T1, the second transistor T2, and the third transistor T3 may each be an oxide semiconductor thin film transistor including a semiconductor layer including an oxide semiconductor, or a silicon semiconductor thin film transistor including a semiconductor layer including polysilicon. According to the type of transistor, a first electrode may be either a source electrode or a drain electrode, and a second electrode may be the other one.

The first transistor T1 may be a driving transistor, a first electrode of the first transistor T1 may be connected to the driving voltage line VDL configured to provide the driving power voltage ELVDD, and a second electrode of the first transistor T1 may be connected to a pixel electrode of the light-emitting diode LED. One of the first electrode and the second electrode of the first transistor T1 may be a drain, and the other thereof may be a source. A gate electrode of the first transistor T1 may be connected to a first node N1. The first transistor T1 may be configured to control the amount of current flowing in the light-emitting diode LED from the driving power voltage ELVDD, according to the voltage at the first node N1.

The second transistor T2 may be a data write transistor. A first electrode of the second transistor T2 may be connected to a data line DL, and a second electrode of the second transistor T2 may be connected to the first node N1. One of the first electrode and the second electrode of the second transistor T2 may be a drain, and the other thereof may be a source. A gate electrode of the second transistor T2 may be connected to a first gate line (hereinafter, referred to as a scan line SL). The second transistor T2 may be turned on when a scan signal is provided to the scan line SL and may electrically connect the data line DL to the first node N1.

The third transistor T3 may be an initialization transistor and/or a sensing transistor. The third transistor T3 may be configured to initialize the pixel electrode of the light-emitting diode LED during some operation periods (e.g., an image display period) of the display panel 10 (see FIG. 2) and to read out a sensing signal of the pixel circuit PC during other operation periods (e.g., a sensing period). The sensing signal may be used to determine and compensate for the deterioration of pixels. One of a first electrode and a second electrode of the third transistor T3 may be a drain, and the other thereof may be a source. The first electrode of the third transistor T3 may be connected to a second node N2, and the second electrode of the third transistor T3 may be connected to a sensing-initialization line SEL. A gate electrode of the third transistor T3 may be connected to a second gate line (hereinafter, a sensing control line CL).

The storage capacitor Cst may be connected between the first node N1 and the second node N2. For example, a first capacitor electrode of the storage capacitor Cst may be connected to the gate electrode of the first transistor T1, and a second capacitor electrode of the storage capacitor Cst may be connected to the pixel electrode of the light-emitting diode LED.

FIG. 5 illustrates that the first transistor T1 to the third transistor T3 each are an NMOS transistor, but one or more embodiments are not limited thereto. For example, one or more of the first transistor T1, the second transistor T2, and the third transistor T3 may each be a PMOS transistor.

FIG. 5 illustrates three transistors, but one or more embodiments are not limited thereto. The pixel circuit PC may include four or more transistors.

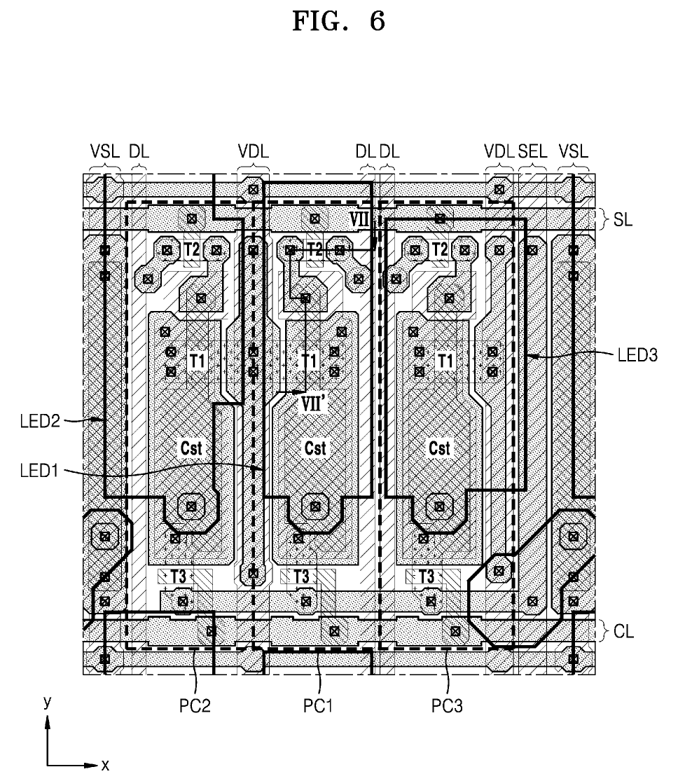

FIG. 6 is a plan view illustrating the first pixel circuit PC1 to the third pixel circuit PC3 and the first light-emitting diode LED1 to the third light-emitting diode LED3 arranged in the display area DA of the display panel 10, according to an embodiment.

Referring to FIG. 6, the first pixel circuit PC1 to the third pixel circuit PC3 may be arranged between two adjacent common voltage lines VSL extending in the first direction (e.g., y direction). The first pixel circuit PC1 to the third pixel circuit PC3 may be arranged in the second direction (e.g., x direction) crossing the first direction (e.g., y direction). In an embodiment, the second pixel circuit PC2 may be arranged on one side (e.g., left side) of the first pixel circuit PC1, and the third pixel circuit PC3 may be arranged on the opposite side (e.g., right side) of the first pixel circuit PC1.

The first pixel circuit PC1 to the third pixel circuit PC3 may each include the first transistor T1, the second transistor T2, the third transistor T3, and the storage capacitor Cst.

In each of the first pixel circuit PC1 to the third pixel circuit PC3, the first transistor T1 and the third transistor T3 may be arranged opposite to the storage capacitor Cst. The second transistor T2 may be arranged adjacent to the first transistor T1. The scan line SL electrically connected to the gate electrode of the second transistor T2 may extend in the second direction (e.g., x direction), and a sensing control line CL electrically connected to the gate electrode of the third transistor T3 may extend in the second direction (e.g., x direction). The scan line SL may be spaced apart from the sensing control line CL, and the first transistor T1, the second transistor T2, the third transistor T3, and the storage capacitor Cst may be arranged between the scan line SL and the sensing control line CL.

The first light-emitting diode LED1 to the third light-emitting diode LED3 may overlap their corresponding pixel circuits. For example, the first light-emitting diode LED1 may overlap the first pixel circuit PC1, the second light-emitting diode LED2 may overlap the second pixel circuit PC2, and the third light-emitting diode LED3 may overlap the third pixel circuit PC3. The first light-emitting diode LED1 to the third light-emitting diode LED3 may be arranged in the second direction (e.g., x direction).

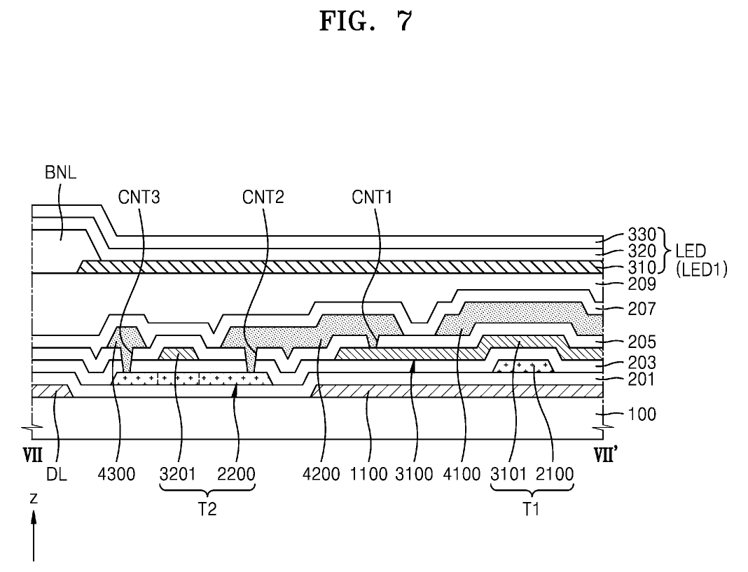

FIG. 7 is a cross-sectional view of the display panel 10 according to an embodiment, taken along a line VII-VII’ of FIG. 6.

Referring to FIG. 7, a light-emitting diode LED (e.g., a first light-emitting diode LED1) may be arranged on the substrate 100, and a pixel circuit (e.g., a first pixel circuit) may be arranged between the substrate 100 and the first light-emitting diode LED1. In this regard, FIG. 7 illustrates the first transistor T1, the second transistor T2, and the storage capacitor Cst included in the pixel circuit PC. FIG. 7 illustrates the first light-emitting diode LED1 and a structure thereunder, but the second light-emitting diode LED2 and the third light-emitting diode LED3 and the structures thereunder may be the same as that shown in FIG. 7.

The substrate 100 may include a glass material, metals, an organic material, or the like. For example, the substrate 100 may include a glass material having silicon oxide (SiO₂) as a principal component, or various materials having flexible or bendable properties, such as polymer resin.

The first transistor T1 may include a first semiconductor layer 2100 and a first gate electrode 3101. The second transistor T2 may include a second semiconductor layer 2200 and a second gate electrode 3201.

The first semiconductor layer 2100 and the second semiconductor layer 2200 may each include an oxide-based material or a silicon-based material (e.g., amorphous silicon, polysilicon, etc.). For example, the first semiconductor layer 2100 and the second semiconductor layer 2200 may each include oxide of at least one material selected from the group consisting of indium (In), gallium (Ga), stannum (Sn), zirconium (Zr), vanadium (V), hafnium (Hf), cadmium (Cd), germanium (Ge), chromium (Cr), titanium (Ti), and zinc (Zn).

The first semiconductor layer 2100 may include a channel area overlapping the first gate electrode 3101 and low-resistance areas (e.g., a source area and a drain area) on both sides of the channel area. The second semiconductor layer 2200 may include a channel area overlapping the second gate electrode 3201 and low-resistance areas (e.g., a source area and a drain area) on both sides of the channel area. The low-resistance areas (e.g., a source area and a drain area) may correspond to the first electrode and the second electrode (e.g., the source and drain) of the transistor described above with reference to FIG. 5.

The first semiconductor layer 2100 and the second semiconductor layer 2200 may each be arranged on a first insulating layer 201 and may be separated from each other. The first insulating layer 201 may be arranged on the substrate 100 and prevent impurities from penetrating into each of the first semiconductor layer 2100 and the second semiconductor layer 2200. The first insulating layer 201 may include an inorganic insulating material such as silicon nitride (SiNx), SiO₂, and/or silicon oxynitride (SiON).

A second insulating layer 203 may be arranged on the first semiconductor layer 2100 and the second semiconductor layer 2200. The second insulating layer 203 may be between the first gate electrode 3101 of the first transistor T1 and the first semiconductor layer 2100 and between the second gate electrode 3201 of the second transistor T2 and the second semiconductor layer 2200. The second insulating layer 203 may include an inorganic insulating material such as SiNx, SiO₂, and/or SiON.

A third insulating layer 205 may be arranged on the first gate electrode 3101 and the second gate electrode 3201. The third insulating layer 205 may include an inorganic insulating material such as SiNx, SiO₂, and/or SiON.

A first conductive layer 3100 may be arranged on the second insulating layer 203. The first conductive layer 3100 may overlap the first semiconductor layer 2100, and a portion of the first conductive layer 3100 that overlaps the first semiconductor layer 2100 may be the first gate electrode 3101. The first conductive layer 3100 may include Mo, Cu, Ti, or the like and have a single-layer structure or a multilayered structure including the above material.

A lower conductive layer 1100 may be between the substrate 100 and the first conductive layer 3100. The lower conductive layer 1100 may be interposed between the substrate 100 and the first insulating layer 201. In an embodiment, the lower surface of the lower conductive layer 1100 may be in direct contact with the upper surface of the substrate 100, and the upper surface of the lower conductive layer 1100 may be in direct contact with the lower surface of the first insulating layer 201. In another embodiment, an inorganic insulating layer may be interposed between the substrate 100 and the lower conductive layer 1100.

The lower conductive layer 1100 may overlap the first conductive layer 3100. The lower conductive layer 1100 may overlap the first semiconductor layer 2100. The area of the lower conductive layer 1100 may be greater than that of the first conductive layer 3100. For example, when the lower conductive layer 1100 is projected in a direction perpendicular to the upper surface of the substrate 100 (when viewed in direction perpendicular to the upper surface of the substrate 100), the first conductive layer 3100 may entirely overlap the lower conductive layer 1100. The lower conductive layer 1100 may not overlap the second semiconductor layer 2200. The lower conductive layer 1100 may include Mo, Cu, Ti, or the like and have a single-layer structure or a multilayered structure including the above material.

The first conductive layer 3100 and the lower conductive layer 1100 that overlap each other may correspond to the capacitor electrodes of the storage capacitor Cst (see FIG. 5). For example, the first conductive layer 3100 may include the first capacitor electrode of the storage capacitor Cst (see FIG. 5), and the lower conductive layer 1100 may include the second capacitor electrode of the storage capacitor Cst (see FIG. 5).

An upper conductive layer 4100 may be arranged on (e.g., above) a third insulating layer 205. The upper conductive layer 4100 may overlap the first conductive layer 3100. The upper conductive layer 4100 may include the second capacitor electrode of the storage capacitor Cst (see FIG. 5). Although not shown in FIG. 7, the upper conductive layer 4100 may be electrically connected to the lower conductive layer 1100. As capacitance accumulates between the lower conductive layer 1100 and the first conductive layer 3100 and between the upper conductive layer 4100 and the first conductive layer 3100, the capacitance of the storage capacitor Cst (see FIG. 5) may be increased.

A bridge 4200 may be arranged on the third insulating layer 205. The bridge 4200 may electrically connect the first conductive layer 3100 to the second semiconductor layer 2200. In other words, the bridge 4200 may electrically connect the first gate electrode 3101 to the second semiconductor layer 2200 and also the first capacitor electrode of the storage capacitor Cst (see FIG. 5) to the second semiconductor layer 2200. The bridge 4200 may be in direct contact with the first conductive layer 3100 through a first contact hole CNT1 penetrating the third insulating layer 205 and also with the second semiconductor layer 2200 through a second contact hole CNT2 penetrating the second insulating layer 203 and the third insulating layer 205. For example, the bridge 4200 may be in direct contact with a first low-resistance area (e.g., the source area) of the second semiconductor layer 2200 through the second contact hole CNT2.

A first conductor 4300 may be arranged on the third insulating layer 205. The first conductor 4300 may be in direct contact with a second low-resistance area (e.g., the drain area) of the second semiconductor layer 2200 through a third contact hole CNT3 penetrating the second insulating layer 203 and the third insulating layer 205. Although not shown in FIG. 7, the first conductor 4300 may be electrically connected to the data line DL.

The upper conductive layer 4100, the bridge 4200, and the first conductor 4300 may be arranged at the same layer (e.g., the third insulating layer 205) and include the same material. The upper conductive layer 4100, the bridge 4200, and the first conductor 4300 may each include Mo, Cu, or/and Ti and have a single-layer structure or a multilayered structure including the above material.

A fourth insulating layer 207 may be arranged on the upper conductive layer 4100, the bridge 4200, and the first conductor 4300. The fourth insulating layer 207 may include an inorganic insulating material such as SiNx, SiO₂, and/or SiON.

A fifth insulating layer 209 may be arranged on the fourth insulating layer 207. The fifth insulating layer 209 may include an organic insulating material, such as acryl, benzocyclobutene (BCB), polyimide (PI), or hexamethyldisiloxane (HMDSO).

The light-emitting diode LED may have a stack structure that includes a pixel electrode 310, an opposite electrode 330 facing the pixel electrode 310, and an intermediate layer 320 between the pixel electrode 310 and the opposite electrode 330.

The pixel electrode 310 may be arranged on the fifth insulating layer 209. The pixel electrode 310 may include transparent conductive oxide such as indium tin oxide (ITO), indium zinc oxide (IZO), zinc oxide (ZnO), indium oxide (In₂O₃), indium gallium oxide (IGO), or aluminum zinc oxide (AZO). In another embodiment, the pixel electrode 310 may include a reflection film including Ag, Mg, Al, Pt, Pd, Au, Ni, Nd, Ir, Cr, or a compound thereof. In another embodiment, the pixel electrode 310 may further include a film including ITO, IZO, ZnO, or In₂O₃over/under the above reflection film. For example, the pixel electrode 310 may have a three-layer structure in which an ITO layer, an Ag layer, and an ITO layer are stacked.

A bank layer BNL may cover edges of the pixel electrode 310 and include a bank opening that overlaps the central portion of the pixel electrode 310. In an embodiment, the bank layer BNL may include an organic insulating material such as PI.

The intermediate layer 320 may contact the pixel electrode 310 through the bank opening of the bank layer BNL, and the opposite electrode 330 may overlap and contact the intermediate layer 320. The stack structure of the pixel electrode 310, the intermediate layer 320, and the opposite electrode 330 that overlap in the bank opening may emit light.

The intermediate layer 320 may include an emission layer. The emission layer may include a high-molecular-weight or low-molecular-weight organic material emitting light of a certain color. As described above with reference to FIG. 3, when the light-emitting diode layer 300 (see FIG. 3) emits blue light, the emission layer may include a high-molecular-weight organic material or a low-molecular-weight organic material emitting blue light.

The opposite electrode 330 may include a conductive material having a low work function. In an embodiment, the opposite electrode 330 may include a transparent (or translucent) layer including Ag, Mg, Al, Pt, Pd, Au, Ni, Nd, Ir, Cr, Li, Ca, or an alloy thereof. In another embodiment, the opposite electrode 330 may further include a layer, such as ITO, IZO, ZnO, or In₂O₃, on the transparent (or translucent) layer including the above material.

Although not shown in FIG. 7, the encapsulation layer 400 (see FIG. 3), the color conversion-transmitting layer 500 (see FIG. 3), the color layer 600, and the light-transmissive substrate layer 700 (see FIG. 3) may be arranged on the opposite electrode 330 as described above with reference to FIG. 3.

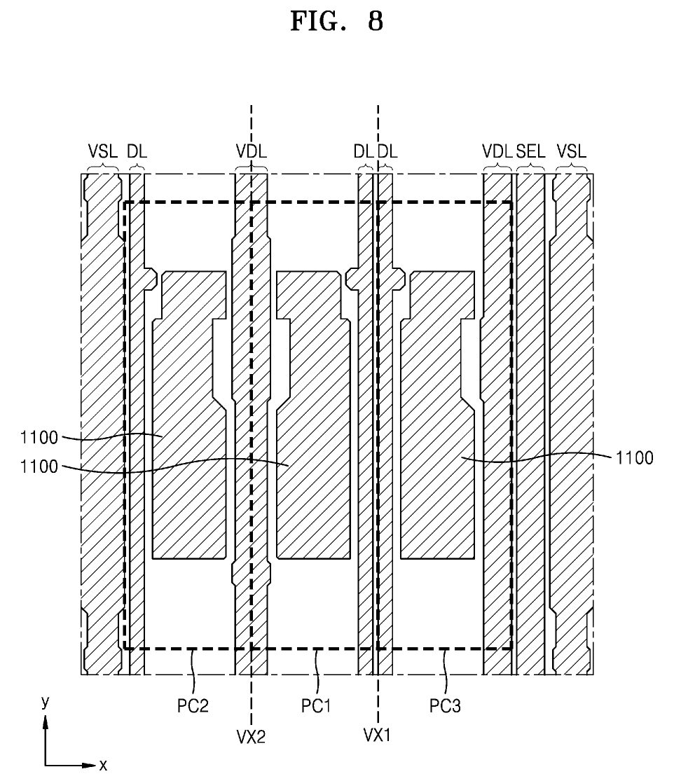

FIGS. 8 to 12 are plan views illustrating a manufacturing process of the display panel 10, according to an embodiment.

Referring to FIGS. 7 and 8, the common voltage line VSL, the driving voltage line VDL, the data line DL, the sensing-initialization line SEL, and the lower conductive layer 1100 may be formed on the substrate 100 (see FIG. 7). The common voltage line VSL, the driving voltage line VDL, the data line DL, the sensing-initialization line SEL, and the lower conductive layer 1100 may be formed in the same process and include the same material.

The driving voltage line VDL, the data line DL, the sensing-initialization line SEL, and the lower c onductive layer 1100 may be arranged between two adjacent common voltage lines VSL. For example, two driving voltage lines VDL, three data lines DL, one sensing-initialization line SEL, and three lower conductive layers 1100 may be arranged between two adjacent common voltage lines VSL.

The data line DL and the driving voltage line VDL electrically connected to the first pixel circuit PC1 may be arranged symmetrically to the data line DL and the driving voltage line VDL electrically connected to the third pixel circuit PC3, with respect to a first virtual line VX1. The first virtual line VX1 may be a virtual line that is between the data line DL electrically connected to the first pixel circuit PC1 and the data line DL electrically connected to the third pixel circuit PC3 and extends in the first direction (e.g., y direction).

The driving voltage line VDL electrically connected to the first pixel circuit PC1 may be electrically connected to the second pixel circuit PC2. In other words, the first pixel circuit PC1 and the second pixel circuit PC2 may share a single driving voltage line VDL. In other words, the first pixel circuit PC1 and the second pixel circuit PC2 may be electrically connected to the same driving voltage line VDL.

The data line DL electrically connected to the first pixel circuit PC1 may be symmetrical to the data line DL electrically connected to the second pixel circuit PC2, with respect to a second virtual line VX2. The second virtual line VX2 may be located between the first pixel circuit PC1 and the second pixel circuit PC2 and pass through the shared driving voltage line VDL.

The data line DL electrically connected to the second pixel circuit PC2 may be arranged adjacent to one of two adjacent common voltage lines VSL. The sensing-initialization line SEL may be arranged between any one of the driving voltage lines VSL and any one of the common voltage lines VSL.

The lower conductive layers 1100 respectively corresponding to the first pixel circuit PC1 to the third pixel circuit PC3 may each have an isolated shape in a plan view and may be separated and spaced apart from each other.

The first insulating layer 201 (see FIG. 7) may be formed on the common voltage line VSL, the driving voltage line VDL, the data line DL, the sensing-initialization line SEL, and the lower conductive layer 1100 shown in FIG. 8.

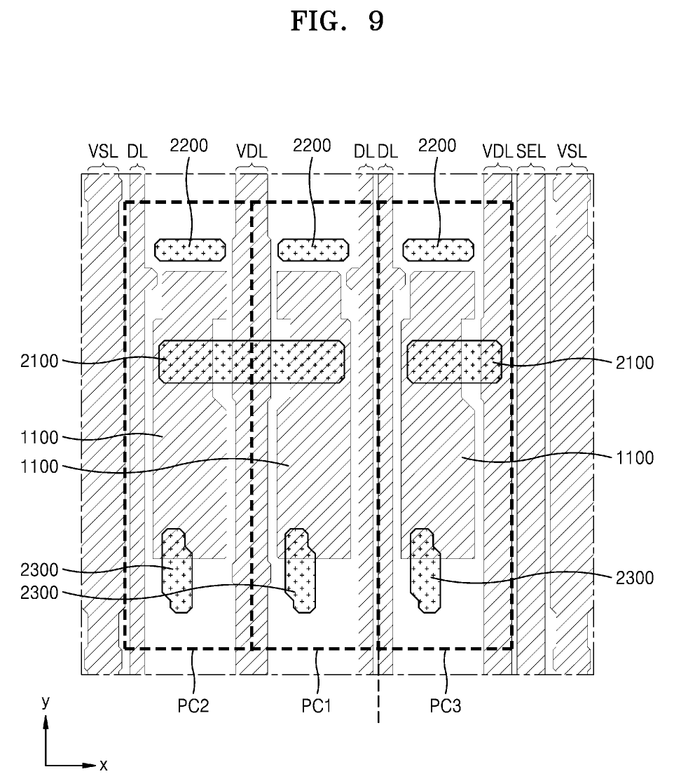

Referring to FIGS. 7 and 9, the first semiconductor layer 2100, the second semiconductor layer 2200, and the third semiconductor layer 2300 may be formed on the first insulating layer 201 (see FIG. 7). The first semiconductor layer 2100, the second semiconductor layer 2200, and the third semiconductor layer 2300 may be formed in the same process and include the same material.

The first semiconductor layer 2100, the second semiconductor layer 2200, and the third semiconductor layer 2300 may be formed in the areas respectively corresponding to the first pixel circuit PC1 to the third pixel circuit PC3. In the same pixel circuit, the first semiconductor layer 2100, the second semiconductor layer 2200, and the third semiconductor layer 2300 may be spaced apart from each other.

The second semiconductor layers 2200 corresponding to different pixel circuits may be separated and spaced apart from each other, and the third semiconductor layers 2300 corresponding to different pixel circuits may be separated and spaced apart from each other. The second semiconductor layers 2200 of the first pixel circuit PC1 to the third pixel circuit PC3 may be separated and spaced apart from each other, and the third semiconductor layers 2300 of the first pixel circuit PC1 to the third pixel circuit PC3 may be separated and spaced apart from each other.

The first semiconductor layer 2100 of the first pixel circuit PC1 may be connected integrally with the first semiconductor layer 2100 of the second pixel circuit PC2. The first semiconductor layer 2100 of the first pixel circuit PC1 may be separated and spaced apart from the first semiconductor layer 2100 of the third pixel circuit PC3.

The first semiconductor layers 2100 of the first pixel circuit PC1 to the third pixel circuit PC3 may respectively overlap the lower conductive layers 1100 of the first pixel circuit PC1 to the third pixel circuit PC3. The first semiconductor layers 2100 of the first pixel circuit PC1 to the third pixel circuit PC3 may respectively overlap their corresponding driving voltage lines VDL. The third semiconductor layers 2300 of the first pixel circuit PC1 to the third pixel circuit PC3 may respectively overlap the lower conductive layers 1100 of the first pixel circuit PC1 to the third pixel circuit PC3. The second semiconductor layers 2200 of the first pixel circuit PC1 to the third pixel circuit PC3 may not overlap the first conductive layers 3100 of the first pixel circuit PC1 to the third pixel circuit PC3, respectively.

The second insulating layer 203 (see FIG. 7) may be formed on the first semiconductor layer 2100, the second semiconductor layer 2200, and the third semiconductor layer 2300 shown in FIG. 9.

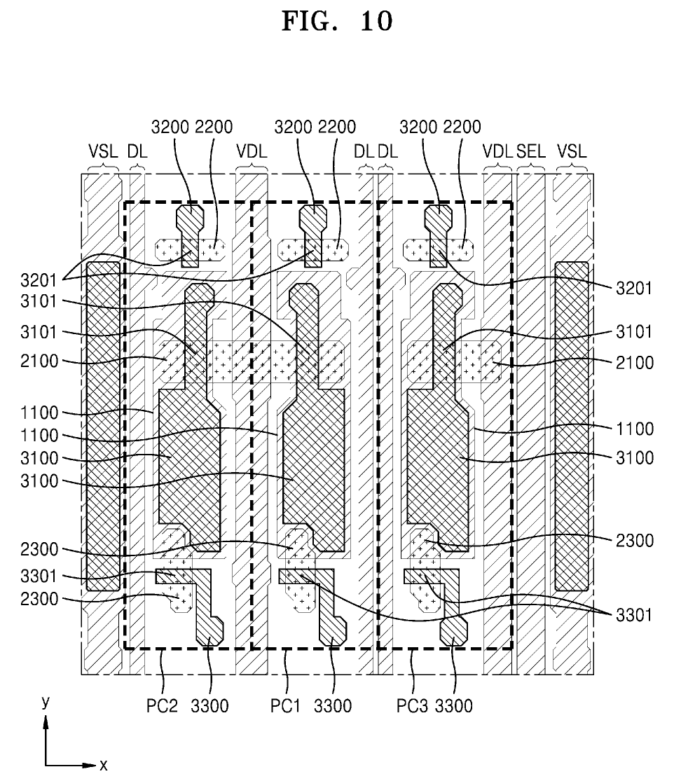

Referring to FIGS. 7 and 10, the first conductive layer 3100, the second conductive layer 3200, and the third conductive layer 3300 are formed on the second insulating layer 203 (see FIG. 7).

The first conductive layer 3100, the second conductive layer 3200, and the third conductive layer 3300 may be formed in the areas respectively corresponding to the first pixel circuit PC1 to the third pixel circuit PC3. In the same pixel circuit, the first conductive layer 3100, the second conductive layer 3200, and the third conductive layer 3300 may be separated and spaced apart from each other.

The first conductive layer 3100 may overlap the first semiconductor layer 2100 and the lower conductive layer 1100. In a plan view, the first conductive layer 3100 may entirely overlap the lower conductive layer 1100 or may be entirely contained within the boundary of the lower conductive layer 100. The area of the lower conductive layer 1100 may be greater than that of the first conductive layer 3100, and all edges defining the shape of the first conductive layer 3100 may lie within and overlap the lower conductive layer 1100 in the plan view. When the first conductive layer 3100 is perpendicularly projected onto the upper surface of the substrate 100 (see FIG. 7), the first conductive layer 3100 may entirely overlap and remain within the boundary of the lower conductive layer 1100 in the plan view.

The first conductive layer 3100 may include the first gate electrode 3101. The first conductive layer 3100 may include a first portion 3101 overlapping the channel area of the first semiconductor layer 2100, and the first portion 3101 described above may correspond to the first gate electrode 3101 of the first transistor T1 (see FIG. 5). The first conductive layer 3100 may include the first capacitor electrode. In other words, the first conductive layer 3100 may constitute the first capacitor electrode. The first conductive layer 3100 may function as the first capacitor electrode and the first gate electrode.

The second conductive layer 3200 may include the gate electrode 3201 of the second transistor T2 (see FIG. 5). In other words, the second conductive layer 3200 may constitute the gate electrode of the second transistor T2 (see FIG. 5).

The third conductive layer 3300 may include the gate electrode 3301 of the third transistor T3 (see FIG. 5). In other words, the third conductive layer 3300 may constitute the gate electrode of the third transistor T3 (see FIG. 5).

The third insulating layer 205 (see FIG. 7) may be formed on the first semiconductor layer 2100, the second semiconductor layer 2200, and the third semiconductor layer 2300 shown in FIG. 10.

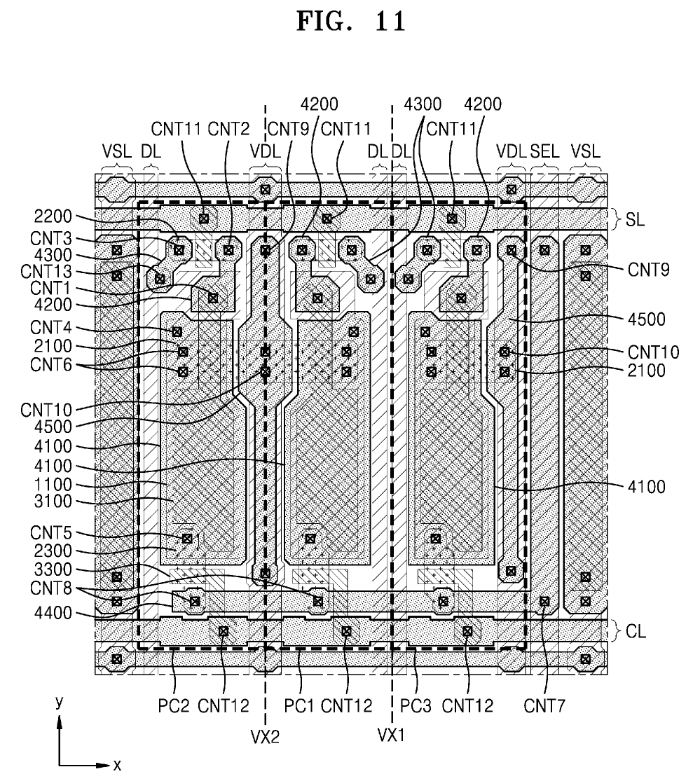

Referring to FIGS. 7 and 11, the upper conductive layer 4100, a first bridge 4200, a second bridge 4300, a third bridge 4400, a fourth bridge 4500, the scan line SL, and the sensing control line CL may be formed on the third insulating layer 205 (see FIG. 7). The upper conductive layer 4100, the first bridge 4200, the second bridge 4300, the third bridge 4400, the fourth bridge 4500, the scan line SL, and the sensing control line CL may be formed in the same process and include the same material.

Each of the first pixel circuit PC1 to the third pixel circuit PC3 may include the upper conductive layer 4100, the first bridge 4200, and the second bridge 4300. In the same pixel circuit, the upper conductive layer 4100, the first bridge 4200, and the second bridge 4300 may be separated and spaced apart from each other.

The upper conductive layer 4100 may overlap the first conductive layer 3100 and the lower conductive layer 1100. The upper conductive layer 4100 may be electrically connected to the lower conductive layer 1100 through a fourth contact hole CNT4. The upper conductive layer 4100 may be in direct contact with the lower conductive layer 1100 through the fourth contact hole CNT4. The fourth contact hole CNT4 may penetrate the insulating layers arranged between the upper conductive layer 4100 and the lower conductive layer 1100. The upper conductive layer 4100 may be electrically connected to the third semiconductor layer 2300 through a fifth contact hole CNT5. The upper conductive layer 4100 may be in direct contact with the third semiconductor layer 2300 through the fifth contact hole CNT5. The fifth contact hole CNT5 may penetrate the insulating layers arranged between the upper conductive layer 4100 and the third semiconductor layer 2300. Each of the fourth contact hole CNT4 and the fifth contact hole CNT5 may overlap the lower conductive layer 1100.

The upper conductive layer 4100 may be electrically connected to the first semiconductor layer 2100 through a sixth contact hole CNT6. The upper conductive layer 4100 may be in direct contact with the first semiconductor layer 2100 through the sixth contact hole CNT6. The sixth contact hole CNT6 may penetrate the insulating layers arranged between the upper conductive layer 4100 and the first semiconductor layer 2100.

The first bridge 4200 may electrically connect the first conductive layer 3100 to the second conductive layer 2200. The first bridge 4200 may be electrically connected to the first conductive layer 3100 through the first contact hole CNT1 and to the second semiconductor layer 2200 through the second contact hole CNT2. The first bridge 4200 may be in direct contact with the first conductive layer 3100 through the first contact hole CNT1 and with the second semiconductor layer 2200 through the second contact hole CNT2. The first contact hole CNT1 may penetrate the insulating layer arranged between the first bridge 4200 and the first conductive layer 3100. The second contact hole CNT2 may penetrate the insulating layers arranged between the first bridge 4200 and the second semiconductor layer 2200.

The first contact hole CNT1 that is a contact point between the first bridge 4200 and the first conductive layer 3100 may overlap the lower conductive layer 1100. The first contact hole CNT1 may correspond to the first node N1 (see FIG. 5) described with reference to FIG. 5. The lower conductive layer 1100 may electrically shield the first contact hole CNT1 that is the contact point between the first bridge 4200 and the first conductive layer 3100, and thus, the occurrence of parasitic capacitance between an adjacent data line DL and the first conductive layer 3100 may be effectively prevented or reduced. In addition, the occurrence of parasitic capacitance in the direction towards the first conductive layer 3100 and the second conductive layer 3200, which is at the same layer as the first conductive layer 3100, may also be prevented or reduced.

The lower conductive layer 1100 does not overlap the second semiconductor layer 2200 and thus not overlap the second contact hole CNT2 that is the contact point between the second semiconductor layer 2200 and the first bridge 4200. As a Comparative Example of the disclosure, when the lower conductive layer 1100 overlaps the second contact hole CNT2, a short circuit between the lower conductive layer 1100 and the first bridge 4200 may occur due to foreign materials that may be present on the second semiconductor layer 2200 during the formation of the second contact hole CNT2. However, because the lower conductive layer 1100 does not overlap the second semiconductor layer 2200, the aforementioned issue may be prevented.

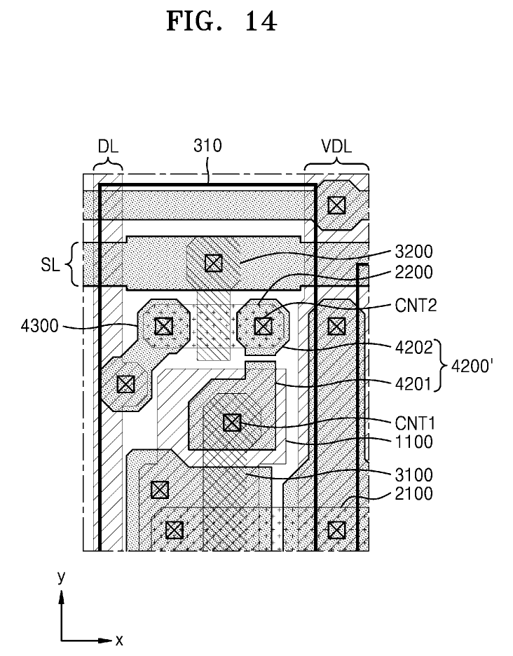

In a plan view (or when viewed in a direction perpendicular to the upper surface of the substrate 100), as the lower conductive layer 1100 is spaced apart from the second semiconductor layer 2200 with a first gap without overlapping the same, a portion of the first bridge 4200 between the first contact hole CNT1 and the second contact hole CNT2 (a portion of the first bridge 4200 that does not overlap the lower conductive layer 1100 and the second semiconductor layer 2200) may be used for repairing the display panel. The repair is described below with reference to FIG. 14.

The second bridge 4300 may electrically connect the second semiconductor layer 2200 to the data line DL. The second bridge 4300 may be electrically connected to the second semiconductor layer 2200 through the third contact hole CNT3 and to the data line DL through a 13^{th} contact hole CNT13. The second bridge 4300 may be in direct contact with the second semiconductor layer 2200 through the third contact hole CNT3 and with the data line DL through the 13^{th} contact hole CNT13. The third contact hole CNT3 may penetrate the insulating layers arranged between the second bridge 4300 and the second semiconductor layer 2200, and the 13^{th} contact hole CNT13 may penetrate the insulating layer arranged between the second bridge 4300 and the data line DL.

In a plan view, the structure of the first pixel circuit PC1 and the structure of the second pixel circuit PC2 are mirror-symmetrical to each other with respect to the second virtual line VX2; thus, the locations of the first contact hole CNT1 to the sixth contact hole CNT6 of the second pixel circuit PC2 may be mirror-symmetrical to the locations of the corresponding first contact hole CNT1 to the sixth contact hole CNT6 of the first pixel circuit PC1 with respect to the second virtual line VX2.

In a plan view, the structure of the first pixel circuit PC1 and the structure of the third pixel circuit PC3 are mirror-symmetrical to each other with respect to the first virtual line VX1; thus, the locations of the first contact hole CNT1 to the sixth contact hole CNT6 of the first pixel circuit PC1 may be mirror-symmetrical to the locations of the corresponding first contact hole CNT1 to the sixth contact hole CNT6 of the third pixel circuit PC3 with respect to the first virtual line VX1.

The third bridge 4400 may electrically connect the sensing-initialization line SEL to the third semiconductor layer 2300 of each pixel circuit. In a plan view, the third bridge 4400 may be bent to have an L shape. A portion of the third bridge 4400 may extend in the first direction (e.g., y direction) and overlap the sensing-initialization line SEL, while another portion of the third bridge 4400 may extend in the second direction (e.g., x direction) and overlap the third semiconductor layer 2300 of each pixel circuit.

The third bridge 4400 may be electrically connected to the sensing-initialization line SEL through a seventh contact hole CNT7 and to the third semiconductor layer 2300 of each pixel circuit through an eighth contact hole CNT8. The third bridge 4400 may be in direct contact with the sensing-initialization line SEL through the seventh contact hole CNT7 and with the third semiconductor layer 2300 of each pixel through the eighth contact hole CNT8. The seventh contact hole CNT7 may penetrate the insulating layers arranged between the third bridge 4400 and the sensing-initialization line SEL, and the eighth contact hole CNT8 may penetrate the insulating layers arranged between the third bridge 4400 and the third semiconductor layer 2300.

The fourth bridge 4500 may overlap the driving voltage line VDL. In this regard, FIG. 11 illustrates that two fourth bridges 4500 respectively overlap two driving voltage lines VDL. The fourth bridges 4500 may be electrically connected to (e.g., in direct contact with) the driving voltage line VDL through a ninth contact hole CNT9.

The fourth bridge 4500 may be electrically connected to the first semiconductor layer 2100 through a tenth contact hole CNT10. For example, the fourth bridge 4500 between the first pixel circuit PC1 and the second pixel circuit PC2 may be electrically connected to (e.g., in direct contact with) the first semiconductor layers 2100 of the first pixel circuit PC1 and the second pixel circuit PC2 that are connected integrally with each other through the tenth contact hole CNT10. The fourth bridge 4500 arranged adjacent to the sensing-initialization line SEL may be electrically connected to (e.g., in direct contact with) the first semiconductor layer 2100 of the third pixel circuit PC3 through the tenth contact hole CNT10.

The scan line SL may extend in the second direction (e.g., x direction) and may be electrically connected to the second conductive layer 3200 of each pixel circuit through an 11^{th} contact hole CNT11. The scan line SL may be in direct contact with the second conductive layer 3200 of each pixel circuit through the 11^{th} contact hole CNT11. The 11^{th} contact hole CNT11 may penetrate the insulating layer arranged between the scan line SL and the second conductive layer 3200.

The sensing control line CL may extend in the second direction (e.g., x direction) and may be electrically connected to the third conductive layer 3300 of each pixel circuit through a 12^{th} contact hole CNT12. The sensing control line CL may be in direct contact with the third conductive layer 3300 of each pixel circuit through the 12^{th} contact hole CNT12. The 12^{th} contact hole CNT12 may penetrate the insulating layer arranged between the sensing control line CL and the third conductive layer 3300.

The fourth insulating layer 207 and the fifth insulating layer 209 (see FIG. 7) may be formed on the upper conductive layer 4100, the first bridge 4200, the second bridge 4300, the third bridge 4400, the fourth bridge 4500, the scan line SL, and the sensing control line CL shown in FIG. 11.

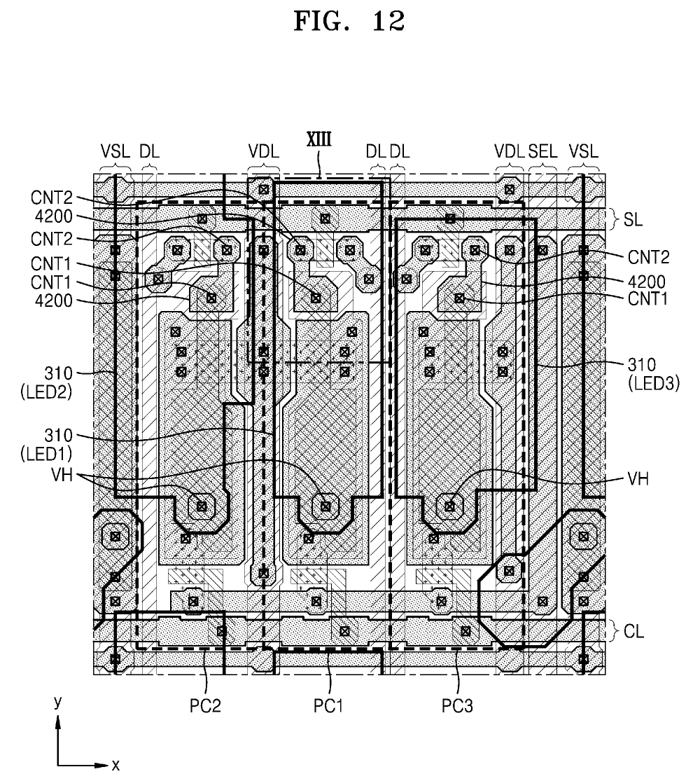

Referring to FIGS. 7 and 12, the pixel electrode 310 is formed on the fifth insulating layer 209 (see FIG. 7). The pixel electrode 310 may overlap each pixel circuit. The pixel electrode 310 on the first pixel circuit PC1 may overlap the first light-emitting diode LED1, the pixel electrode 310 on the second pixel circuit PC2 may overlap the second light-emitting diode LED2, and the pixel electrode 310 on the third pixel circuit PC3 may overlap the third light-emitting diode LED3.

The pixel electrode 310 on the first pixel circuit PC1 may be electrically connected to the first pixel circuit PC1 through a via hole VH. For example, the pixel electrode 310 on the first pixel circuit PC1 may be electrically connected to the upper conductive layer 4100 (see FIG. 11) of the first pixel circuit PC1 through the via hole VH.

The pixel electrode 310 on the second pixel circuit PC2 may be electrically connected to the second pixel circuit PC2 through the via hole VH. For example, the pixel electrode 310 on the second pixel circuit PC2 may be electrically connected to the upper conductive layer 4100 (see FIG. 11) of the second pixel circuit PC2 through the via hole VH.

The pixel electrode 310 on the third pixel circuit PC3 may be electrically connected to the third pixel circuit PC3 through the via hole VH. For example, the pixel electrode 310 on the third pixel circuit PC3 may be electrically connected to the upper conductive layer 4100 (see FIG. 11) of the third pixel circuit PC3 through the via hole VH.

The pixel electrode 310 electrically connected to each pixel circuit may overlap the first contact hole CNT1 of its corresponding pixel circuit and may electrically protect the same. For example, the occurrence of parasitic capacitance between the first conductive layer 3100 and peripheral structures may be restricted due to an adjacent pixel electrode 310 and the structure around the first contact hole CNT1.

The pixel electrode 310 electrically connected to each pixel circuit may entirely overlap the first bridge 4200 of its corresponding pixel circuit. The pixel electrode 310 electrically connected to each pixel circuit may entirely overlap the second contact hole CNT2 of its corresponding pixel circuit.

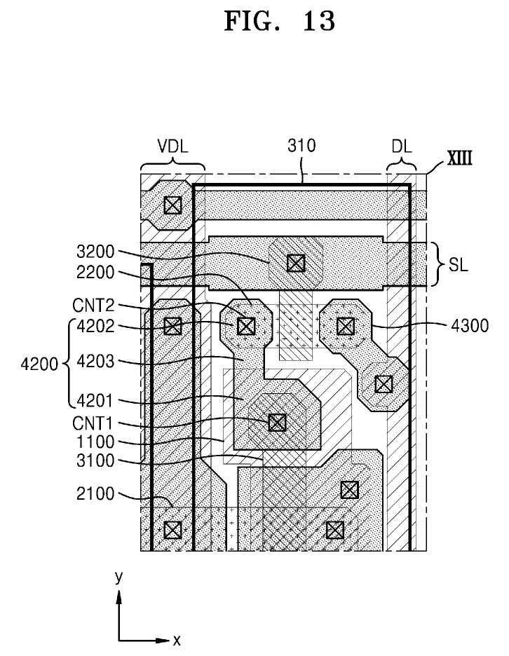

FIG. 13 is an enlarged view of a portion of a display panel according to an embodiment and corresponds to a plan view of enlarged region XIII of FIG. 12.

Referring to FIG. 13, the first bridge 4200 may include a first portion 4201, a second portion 4202, and a third portion 4203 between the first portion 4201 and the second portion 4202. The first portion 4201 may be electrically connected to (e.g., in contact with) the first conductive layer 3100 and may overlap the lower conductive layer 1100. The second portion 4202 may overlap the second semiconductor layer 2200 and may be electrically connected to (e.g., in contact with) the second semiconductor layer 2200.

Because the lower conductive layer 1100 does not overlap the second semiconductor layer 2200, the risk of an electrical connection (i.e., a short circuit) between the lower conductive layer 1100 and the first bridge 4200, which may be potentially caused due to foreign materials possibly present on the second semiconductor layer 2200 during the manufacturing process of the display panel, may be prevented. Accordingly, a negative repair process, in which a defective pixel is turned off using the third portion 4203, may be reliable performed. Although the stack structure of the insulating layers is arranged between the third portion 4203 of the first bridge 4200 and the substrate 100 (see FIG. 7), no conductive material is present therebetween. Therefore, an unnecessary electrical connection (e.g., a short circuit) during the above-described repair process may be prevented.

In a cross-sectional view, the lower conductive layer 1100 may be arranged under the first contact hole CNT1, and the pixel electrode 310 may be arranged above the first contact hole CNT1. In a cross-sectional view, the lower conductive layer 1100, the first contact hole CNT1, and the pixel electrode 310 may form a sandwich-overlapping structure in which the first contact hole CNT1 vertically overlaps the lower conductive layer 1100 and the pixel electrode 310 while being arranged therebetween. This structural configuration may stabilize the gate-source voltage Vgs of the first transistor T1 (see FIG. 5) by minimizing variations caused by the surrounding structure of the first contact hole CNT1. The variations in the gate-source voltage Vgs of the first transistor T1 (see FIG. 5) may otherwise cause a change in the current flowing through its corresponding light-emitting diode, and the current change may lead to a change in luminance. However, according to an embodiment, variations in the gate-source voltage Vgs of the first transistor T1 (see FIG. 5) may be effectively prevented because of the above structure, and thus, high-quality images may be provided.

Because the lower conductive layer 1100 overlaps the first contact hole CNT1 while being arranged at the same layer as the data line DL, parasitic capacitance between the data line DL and the first conductive layer 3100 may be effectively suppressed. In addition, because the lower conductive layer 1100 overlaps the first conductive layer 3100, the occurrence of unnecessary parasitic capacitance between the second conductive layer 3200 and the first conductive layer 3100 providing scan signals and/or between the scan line SL and the first conductive layer 3100 may be reduced. The occurrence of parasitic capacitance may be reduced not only between the first conductive layer 3100 and the above-described structure around the first contact hole CNT1 but also in other regions of a pixel circuit.

FIG. 14 is a plan view of an enlarged portion of a display panel, according to an embodiment. FIG. 14 illustrates a portion of a pixel circuit according to any one embodiment of the display panel. Referring to FIG. 14, a first bridge 4200’ of any one of the pixel circuits included in the display panel may include a first portion 4201 and a second portion 4202 that are separated from each other.

In an embodiment, when any one pixel is defective, the first portion 4201 of the first bridge 4200’ of a pixel circuit corresponding to the defective pixel may be electrically isolated from or physically separated from the second portion 4202 thereof by cutting a third portion 4103 (see FIG. 13) of the first bridge 4200’. As a result, in the defective-repaired pixel, the third portion 4103 is removed from the first bridge 4200’ as shown in FIG. 14. Because the lower conductive layer 1100 overlaps only the first portion 4201, the cutting process may be easily performed without affecting other components (e.g., layers, electrodes, wiring, etc.), and the lower conductive layer 1100 may not overlap the separation region between the first portion 4201 and the second portion 4202 of the first bridge 4200’. The cutting process may be performed using, for example, laser. The aforementioned pixel circuit may be in an off state through the cutting process, and a repair process (a type of negative repair) for turning off a defective pixel may be performed. As an alternative to physical removal, the third portion 4103 may be electrically isolated by applying a localized electrical or thermal stimulus (e.g., a high-current pulse or a focused laser) configured to increase the electrical resistance or induce breakdown in a fuse-like region of the bridge. This process may disable current flow through the third portion 4103 without physically severing it.

In an embodiment, most of the pixel circuits of the display panel may have the structures described above with reference to FIGS. 6 to 13, while any one of the pixel circuits may have the structure in which the first portion 4201 and the second portion 4202 of the first bridge 4200’ are separated from each other, as illustrated in FIG. 14.

According to one or more embodiments, a display panel may include a substrate, a first transistor including a first semiconductor layer, a second transistor including a second semiconductor layer, a first conductive layer including a first gate electrode of the first transistor that overlaps a channel area of the first semiconductor layer in a plan view, a first bridge connecting the first conductive layer to the second semiconductor layer, a lower conductive layer between the substrate and the first conductive layer, the lower conductive layer overlapping, in the plan view, a contact point between the first conductive layer and the first bridge, and a light-emitting diode including a pixel electrode connected to the first transistor.

The pixel electrode of the light-emitting diode overlaps the contact point between the first conductive layer and the first bridge in the plan view.

The display panel may further include a storage capacitor connected to the first transistor and the second transistor, the storage capacitor including a first capacitor electrode and a second capacitor electrode, wherein the first conductive layer may include the first capacitor electrode of the storage capacitor, and the lower conductive layer may include the second capacitor electrode of the storage capacitor.

The display panel may further include an upper conductive layer above the first conductive layer and, in the plan view, overlapping the first conductive layer, wherein the upper conductive layer is connected to the lower conductive layer.

The upper conductive layer and the first bridge may be on a same layer and are spaced apart from each other.

In the plan view, the first conductive layer may not overlap the second semiconductor layer.

In the plan view, the lower conductive layer may not overlap the second semiconductor layer.

The display panel may further include a data line connected to the second semiconductor layer of the second transistor, wherein the data line and the lower conductive layer may be on a same layer.

The first bridge may include: a first portion being in contact with the first conductive layer and, in the plan view, overlapping the lower conductive layer; a second portion being in contact with and, in the plan view, overlapping the second semiconductor layer; and a third portion between the first portion and the second portion, wherein a stack structure of insulating layers is between the third portion and the substrate.

According to one or more embodiments, an electronic device may include: a substrate; a plurality of pixel circuits on the substrate; and a first light-emitting diode connected to a first pixel circuit among the plurality of pixel circuits, wherein the first pixel circuit may include: a driving transistor including a first semiconductor layer; a data write transistor including a second semiconductor layer; a first conductive layer including a first gate electrode of the driving transistor that overlaps a channel area of the first semiconductor layer in a plan view; a first bridge connecting the first conductive layer to the second semiconductor layer; and a lower conductive layer between the substrate and the first conductive layer, the lower conductive layer overlapping, in the plan view, a contact point between the first conductive layer and the first bridge.

The pixel electrode of the first light-emitting diode overlaps the contact point between the first conductive layer and the first bridge in the plan view.

The electronic device may include a storage capacitor connected to the driving transistor and the data write transistor, the storage capacitor including a first capacitor electrode and a second capacitor electrode, wherein the first conductive layer may include the first capacitor electrode of the storage capacitor, and the lower conductive layer may include the second capacitor electrode of the storage capacitor.

The electronic device may include an upper conductive layer above the first conductive layer and, in the plan view, overlapping the first conductive layer, wherein the upper conductive layer may be connected to the lower conductive layer.

The upper conductive layer and the first bridge may be on a same layer and are spaced apart from each other.

In the plan view, the first conductive layer may not overlap the second semiconductor layer.

The first bridge may include: a first portion being in contact with the first conductive layer and, in the plan view, overlapping the lower conductive layer; a second portion being in contact with and, in the plan view, overlapping the second semiconductor layer; and a third portion between the first portion and the second portion. A stack structure of insulating layers may be between the third portion and the substrate.

A second pixel circuit among the plurality of pixel circuits may include a driving transistor, a data write transistor, and a conductive layer including a gate electrode of the driving transistor of the second pixel circuit. The second pixel circuit may include a second bridge that may include a first portion being in contact with the conductive layer and a second portion being in contact with a semiconductor layer of the driving transistor of the second pixel circuit, and the first portion and the second portion of the second bridge may be separated from each other.

The electronic device may include an additional lower conductive layer interposed the substrate and the conductive layer and overlapping, in the plan view, a contact point between the conductive layer and the second bridge of the second pixel circuit. In the plan view, the lower conductive layer may not overlap a portion in which the first portion and the second portion of the second bridge of the second pixel circuit are separated.

According to one or more embodiments, a display panel may include: a pixel circuit; and a light-emitting diode connected to the pixel circuit. The pixel circuit may include: a driving transistor configured to supply a driving power voltage to the light-emitting diode, the driving transistor including a first semiconductor layer; a data write transistor configured to be turned on by a scan signal to connect a data line to a gate electrode of the driving transistor, the data write transistor including a second semiconductor layer; a first conductive layer including the gate electrode of the driving transistor; a bridge connecting the first conductive layer to the second semiconductor layer; an upper conductive layer above the first conductive layer; and a lower conductive layer below the first conductive layer, and overlapping, in a plan view, a contact point between the first conductive layer and the bridge.

The light-emitting diode may include a pixel electrode that overlaps the contact point between the first conductive layer and the bridge in the plan view.

According to some embodiments, a display panel with improved display quality through a relatively simple structure and an electronic device including the display panel may be provided. The above effect is merely an example, and the scope of the disclosure is not limited thereto.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display panel comprising:
a substrate;
a first transistor comprising a first semiconductor layer;
a second transistor comprising a second semiconductor layer;
a first conductive layer comprising a first gate electrode of the first transistor that overlaps a channel area of the first semiconductor layer in a plan view;
a first bridge connecting the first conductive layer to the second semiconductor layer;
a lower conductive layer between the substrate and the first conductive layer, the lower conductive layer overlapping, in the plan view, a contact point between the first conductive layer and the first bridge; and
a light-emitting diode comprising a pixel electrode connected to the first transistor.

2. The display panel of claim 1, wherein the pixel electrode of the light-emitting diode overlaps the contact point between the first conductive layer and the first bridge in the plan view.

3. The display panel of claim 1, further comprising a storage capacitor connected to the first transistor and the second transistor, the storage capacitor comprising a first capacitor electrode and a second capacitor electrode,
wherein the first conductive layer comprises the first capacitor electrode of the storage capacitor, and
the lower conductive layer comprises the second capacitor electrode of the storage capacitor.

4. The display panel of claim 3, further comprising an upper conductive layer above the first conductive layer and, in the plan view, overlapping the first conductive layer,
wherein the upper conductive layer is connected to the lower conductive layer.

5. The display panel of claim 4, wherein the upper conductive layer and the first bridge are on a same layer and are spaced apart from each other.

6. The display panel of claim 1, wherein, in the plan view, the first conductive layer does not overlap the second semiconductor layer.

7. The display panel of claim 1, wherein, in the plan view, the lower conductive layer does not overlap the second semiconductor layer.

8. The display panel of claim 1, further comprising a data line connected to the second semiconductor layer of the second transistor,
wherein the data line and the lower conductive layer are on a same layer.

9. The display panel of claim 1, wherein the first bridge comprises:
a first portion being in contact with the first conductive layer and, in the plan view, overlapping the lower conductive layer;
a second portion being in contact with and, in the plan view, overlapping the second semiconductor layer; and
a third portion between the first portion and the second portion,
wherein a stack structure of insulating layers is between the third portion and the substrate.

10. An electronic device comprising:
a substrate;
a plurality of pixel circuits on the substrate; and
a first light-emitting diode connected to a first pixel circuit among the plurality of pixel circuits,
wherein the first pixel circuit comprises:
a driving transistor comprising a first semiconductor layer;
a data write transistor comprising a second semiconductor layer;
a first conductive layer comprising a first gate electrode of the driving transistor that overlaps a channel area of the first semiconductor layer in a plan view;
a first bridge connecting the first conductive layer to the second semiconductor layer; and
a lower conductive layer between the substrate and the first conductive layer, the lower conductive layer overlapping, in the plan view, a contact point between the first conductive layer and the first bridge.

11. The electronic device of claim 10, wherein the pixel electrode of the first light-emitting diode overlaps the contact point between the first conductive layer and the first bridge in the plan view.

12. The electronic device of claim 10, further comprising a storage capacitor connected to the driving transistor and the data write transistor, the storage capacitor comprising a first capacitor electrode and a second capacitor electrode,
wherein the first conductive layer comprises the first capacitor electrode of the storage capacitor, and
the lower conductive layer comprises the second capacitor electrode of the storage capacitor.

13. The electronic device of claim 12, further comprising an upper conductive layer above the first conductive layer and, in the plan view, overlapping the first conductive layer,
wherein the upper conductive layer is connected to the lower conductive layer.

14. The electronic device of claim 13, wherein the upper conductive layer and the first bridge are on a same layer and are spaced apart from each other.

15. The electronic device of claim 10, wherein, in the plan view, the first conductive layer does not overlap the second semiconductor layer.

16. The electronic device of claim 10, wherein the first bridge comprises:
a first portion being in contact with the first conductive layer and, in the plan view, overlapping the lower conductive layer;
a second portion being in contact with and, in the plan view, overlapping the second semiconductor layer; and
a third portion between the first portion and the second portion, and
a stack structure of insulating layers is between the third portion and the substrate.

17. The electronic device of claim 10, wherein a second pixel circuit among the plurality of pixel circuits comprises a driving transistor, a data write transistor, and a conductive layer comprising a gate electrode of the driving transistor of the second pixel circuit,
the second pixel circuit further comprises a second bridge that comprises a first portion being in contact with the conductive layer and a second portion being in contact with a semiconductor layer of the driving transistor of the second pixel circuit, and
the first portion and the second portion of the second bridge are separated from each other.

18. The electronic device of claim 17, further comprising an additional lower conductive layer interposed the substrate and the conductive layer and overlapping, in the plan view, a contact point between the conductive layer and the second bridge of the second pixel circuit,
wherein, in the plan view, the lower conductive layer does not overlap a portion in which the first portion and the second portion of the second bridge of the second pixel circuit are separated.

19. A display panel comprising:
a pixel circuit; and
a light-emitting diode connected to the pixel circuit,
wherein the pixel circuit comprises:
a driving transistor configured to supply a driving power voltage to the light-emitting diode, the driving transistor comprising a first semiconductor layer;
a data write transistor configured to be turned on by a scan signal to connect a data line to a gate electrode of the driving transistor, the data write transistor comprising a second semiconductor layer;
a first conductive layer comprising the gate electrode of the driving transistor;
a bridge connecting the first conductive layer to the second semiconductor layer;
an upper conductive layer above the first conductive layer; and
a lower conductive layer below the first conductive layer, and overlapping, in a plan view, a contact point between the first conductive layer and the bridge.

20. The display panel of claim 19, wherein the light-emitting diode comprises a pixel electrode that overlaps the contact point between the first conductive layer and the bridge in the plan view.
